(19) United States
(12) Patent Application Publication
(10) Pub. No.: US 2017/0150573 A1
(43) Pub. Date: May 25, 2017

(54) ORGANIC ELECTRONIC LIGHTING SYSTEM

(71) Applicant: Cambridge Display Technology Limited, Godmanchester (GB)

(72) Inventors: Natasha M.J. Conway, Histon (GB); Colin Baker, Cambridge (GB); Philip Benzie, Godmanchester (GB); Alexander Doust, Cambridge (GB); Niall MacCarthy, Godmanchester (GB)

(73) Assignee: Cambridge Display Technology Limited, Godmanchester (JP)

(21) Appl. No.: 15/322,371

(22) PCT Filed: Jun. 19, 2015
(86) PCT No.: PCT/EP2015/063835

§ 371 Date: Dec. 27, 2016

(30) Foreign Application Priority Data
Jun. 27, 2014 (GB) 1411493.8

(51) Int. Cl. H05B 33/08; H01L 51/52; H01L 27/32; H01L 51/50

(52) U.S. Cl. CPC H05B 33/0896; H01L 51/5088; H01L 51/5206; H01L 27/3213; H01L 2251/562

(57) ABSTRACT

A method of increasing the lifetime of an ITO-free organic lighting system comprises: providing an organic lighting element having a substrate (12) bearing a set of anode electrode metal tracks (14), a conductive organic layer (16) over said metal tracks, an organic light emitting layer (18) over said conductive organic layer, and a cathode electrode layer (20) over said organic light emitting layer, wherein said metal comprises copper, and wherein said conductive organic layer comprises a doped conducting polymer, and driving the organic lighting element with a pulsed current drive. A biphasic pulse is employed having a first, on-phase with a defined current drive and a second, off-phase with a drive having a defined potential difference of zero volts across the lighting element. The anode electrode metal may have a higher work function than the cathode electrode layer. During said zero level drive portion the different work functions provide a reverse bias electric field within the organic lighting element.

### FIELD OF THE INVENTION

This invention relates to organic electronic lighting systems such as OLED (organic light emitting diode) lighting systems and, in particular, to techniques for reducing the cost and increasing the lifetime of such systems.

### BACKGROUND TO THE INVENTION

Reducing the cost and increasing the lifetime of organic light emitting devices is important to the success of this technology. Typically such devices incorporate one transparent electrode, generally ITO (indium tin oxide) to enable the light to escape from the structure. Use of such material provides relatively good lateral conductivity and performance but is expensive and, in the long term, is not desirable for large scale production. The degradation of ITO-based devices has been investigated in “White-Light Generation and OLED Lifetime Issues”, by Aaron R. Johnson, Thesis, 2008; and in “Effect of driving method on the degradation of organic light emitting diodes”, P. Cusumano, F. Buttitta, A. Di Cristofalo, C. Cali, Synthetic Metals 139 (2003) 657-661. In this context it appears that pulsed operation of an OLED may mitigate degradation, although the observations are somewhat contradictory. An OLED pre-charge circuit is described in U.S. Pat. No. 7,079,092.

One alternative to the use of ITO is to employ an anode metal grid rather than a continuous anode electrode; in this case the metal grid provides for current distribution within the panel and the conductive polymer layer needs to exhibit sufficiently good lateral conductivity to provide even current distribution within a cell. In such a system it is observed that improved lifetimes are obtained when using gold. It would, however, be desirable to be able to use a wider range of materials, in particular copper. However in practice devices with copper anode electrode tracks are observed to have only short life times, typically a few hours.

### SUMMARY OF THE INVENTION

According to the present invention there is therefore provided an ITO-free organic lighting system, the system comprising: a substrate bearing a set of anode electrode metal tracks; a conductive organic layer over said metal tracks; an organic light emitting layer over said conductive organic layer; and a cathode electrode layer over said organic light emitting layer; and a driver system having an output electronically coupled to said anode electrode metal tracks and to said cathode electrode layer, to drive said organic light emitting layer with a drive current to emit light; wherein said drive current is pulsed such that an operational lifetime of said lighting system is increased.

Experimentally this approach has been demonstrated to mitigate device failure, in particular where a copper anode electrode grid is employed—which facilitates good performance at low cost. Without wishing to be bound by theory it is speculated that this may be related to a reduction in migration of copper ions into the conductive organic layer.

In embodiments a percentage on-time of the light emitting layer is reduced from 100%, and a peak value of the drive current is increased, such that for a given, for example maximum, light output, the light output is maintained whilst driving the organic light emitting device with a reduced on-time.

In some embodiments the conductive organic layer is deposited directly onto the metal (copper) tracks. In other embodiments a protective, barrier layer may be provided between the metal tracks and the conductive organic layer; this layer may be a doped conductive polymer layer.

Although the copper may be in the form of a copper alloy to mitigate electromigration, surprisingly embodiments of the invention work well with low cost “pure” copper, that is copper which is not a deliberate alloy but which nonetheless may contain impurities up to, for example, 0.1% 0.5%, 1%, 2%, 3% or even 5%.

Nonetheless, in embodiments of this aspect of the invention, and also in embodiments of the other aspects of the invention described below, the anode electrode metal comprises a NiP alloy (a mixture of nickel and phosphorus), in particular a copper NiP alloy. Then, preferably, the NiP alloy forms a protective or a capping layer on the anode electrode metal, for example copper. This may be deposited by electro- or electrolessly plating the NiP alloy on the metal, for example copper. It has been found that this helps to increase device lifetime.

Also surprisingly, it has been found that with drive schemes of the type described the anode electrode metal may be deposited by electroplating or electroless deposition (for example on a thin printed conductive template). These types of deposition inherently require mobile ions and thus are techniques which one might expect should particularly be avoided, despite the advantage of being able to deposit a relatively thick layer of metal in a short time. However, the techniques we describe provide sufficient benefit to enable this type of deposition process to be employed. As previously mentioned, a preferred metal is copper but silver may also be used.

In embodiments the light emitting structure is an organic light emitting diode (OLED) structure. This may comprise a light emitting polymer (LEP), or small-molecule, stack between a hole injection layer and a cathode layer. As the skilled person will appreciate, the LEP stack may comprise multiple layers depending on the construction of the OLED. Similarly, as described later, the cathode layer may comprise multiple layers of different materials. The skilled person will further appreciate that where in this specification one layer is described as being over another layer this does not necessarily mean that the layers are directly on top of one another.

In preferred embodiments the conductive organic layer is a hole injection layer, preferably comprising a doped conducting polymer, in embodiments (polyethylene dioxythiophene) (PEDT), optionally substituted. The dopant may be a charge-balancing polyacid such as polystyrene sulphonate (PSS).

In embodiments the light emitting structure is a bottom-emitting structure; this may be in the form of a lighting tile. The driver system may be integrated with such a structure/tile or separate from the structure/tile.

In a related aspect the invention provides a method of increasing the lifetime of an organic lighting system, in particular an ITO-free organic lighting system, the method comprising: providing an organic lighting element comprising: a substrate bearing a set of anode electrode metal tracks; a conductive organic layer over said metal tracks; an organic light emitting layer over said conductive organic layer; and a cathode electrode layer over said organic light emitting layer; wherein said metal comprises copper, and wherein said conductive organic layer comprises a doped conducting polymer; and driving said organic lighting element with a pulsed current drive.

As used herein the lifetime of an organic lighting system may be defined either by the “T₅₀ luminance”, the time in hours it takes the luminance of a device to decrease to half its value at turn on, or by the “T₉₀ luminance”, the time in hours it takes the luminance of a device to decrease to 90% of its value at turn on.

In some preferred embodiments the current drive employs a biphasic pulse having a first, on-phase in which the lighting element is driven with a defined current and a second, off-phase in which the lighting element is driven with a defined potential difference across the element (OLED), in embodiments zero volts.

Thus in embodiments the current drive is a pulsed current drive with forward drive and substantially zero level drive portions. Where the anode electrode metal has a higher work function than the cathode electrode layer during the zero level drive portion of the current drive these different work functions provide a reverse bias electric field within the lighting element which, it is speculated, helps to clear unwanted charged impurities from the conductive organic layer. More generally, to achieve this a portion of an anode structure of the organic lighting element should have a higher work function than a portion of the cathode electrode structure of the element, in particular a cathode metal part of the cathode electrode structure. Alternatively the relevant internal electric field may be generated by one or both of the hole injection layer and an electron injection layer (if present) in addition to or instead of the anode electrode metal/cathode electrode layer, in which case the cathode electrode layer may be considered as including an electron injection layer (where present). Where the current drive is a pulsed current drive with forward drive and substantially zero level drive portions, preferably the zero level drive is an active drive to zero volts rather than just leaving the one electrode of the lighting element floating.

The frequency of the pulsed current drive apparently effects the device lifetime; preferably a frequency of less than 1000 Hz is employed. Preferably the frequency is greater than 30 Hz to avoid visual flicker. Similarly the duty cycle of the pulsed current (the percentage of time for which the forward drive is on) also appears to effect lifetime although a low percentage on-time also reduces the brightness of the lighting element. In some preferred embodiments the duty cycle (percentage on time) is at least 40%; an upper limit of the range may be 85%, 90%, 95% or 98%.

In a further related aspect the invention provides an OLED lighting system including an OLED lighting element with at least one copper electrode and a driver, wherein said driver is configured to drive said OLED lighting element with a pulsed current drive at a maximum light output of the system.

In some preferred embodiments the driver is configured to drive the OLED lighting element with a biphasic pulse. The biphasic pulse has a first, on-phase in which the OLED lighting element is driven with a defined current and a second, off-phase in which the OLED lighting element is actively driven with a defined potential difference across the OLED, in embodiments zero volts.

### BRIEF DESCRIPTION OF THE DRAWINGS

These and other aspects of the invention will now be further described, by way of example only, with reference to the accompanying Figures in which:

FIGS. 1a to 1e show, respectively, a cross-section through an OLED lighting tile, and a view of a front, light-emitting face of the tile, an example of an ITO-free lighting system according to an embodiment of the invention, a first example of an OLED drive circuit for implementing an embodiment of the invention, and a second example of an OLED drive circuit for implementing an embodiment of the invention;

FIGS. 2a and 2b show graphs of luminance against time for direct current drive schemes and pulsed drive schemes according to embodiments on the invention; and

FIG. 3 shows a graph of luminance against time illustrating the effect of using different anode metals.

### DETAILED DESCRIPTION OF PREFERRED EMBODIMENTS

### Organic Light Emitting Structures

In this specification references to organic LEDs include organometallic LEDs, and OLEDs fabricated using either polymers or small molecules. Examples of polymer—based OLEDs are described in WO 90/13148, WO 95/06400 and WO 99/48160; examples of so called small molecule based devices are described in U.S. Pat. No. 4,539,507.

OLED devices (which here includes organometallic devices and devices including one or more phosphors) may be fabricated using either polymers or small molecules in a range of colours and in multi-coloured displays depending upon the materials used. For general background information reference may be made, for example, to WO90/13148, WO95/06400, WO99/48160 and U.S. Pat. No. 4,539,570, as well as to “Organic Light Emitting Materials and Devices” edited by Zhigang Li and Hong Meng, CRC Press (2007), ISBN 10: 1-57444-574X, which describes a number of materials and devices, both small molecule and polymer.

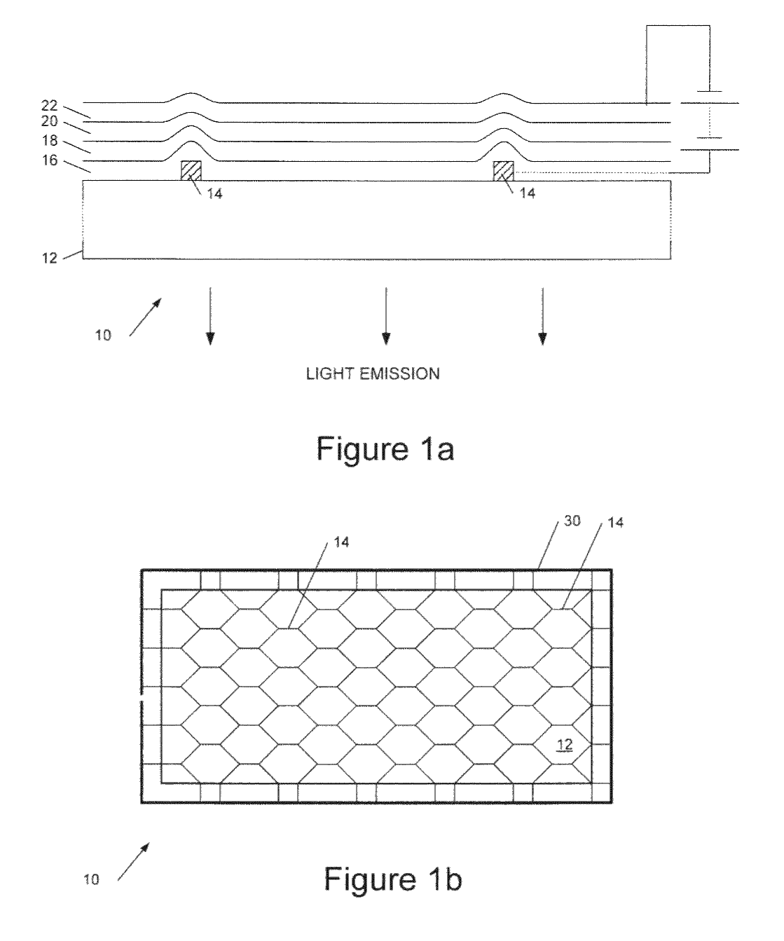

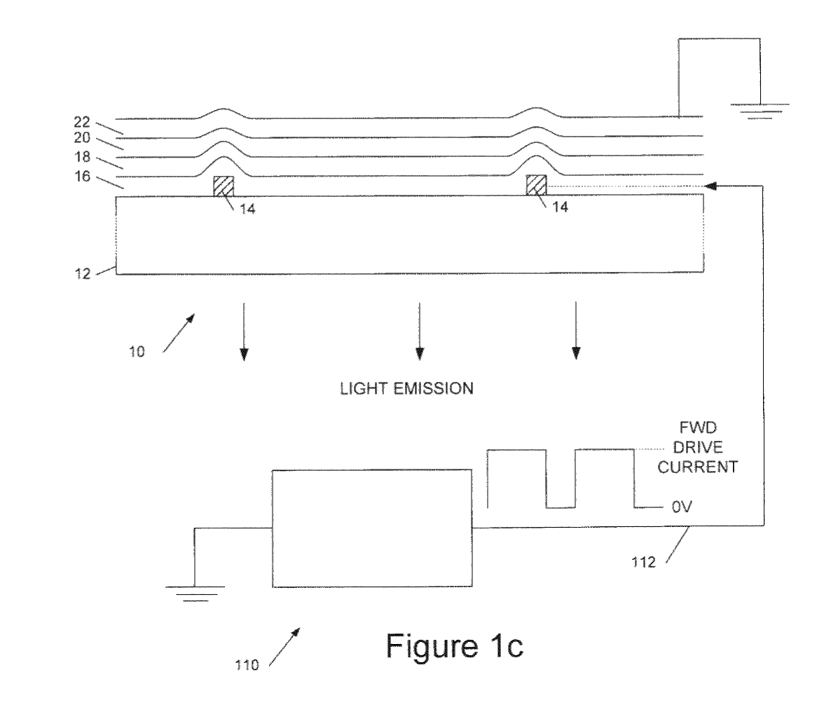

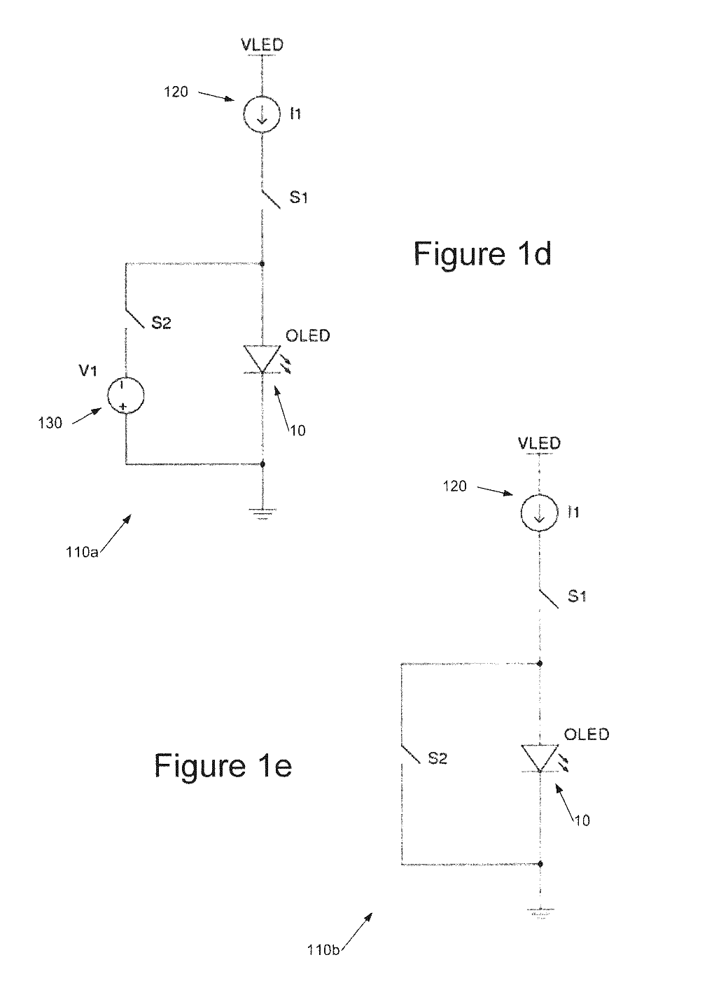

To aid in understanding embodiments of the invention it is helpful to describe an example structure of an OLED lighting tile. Thus referring to FIG. 1a, this shows a vertical cross-section through a portion of an OLED lighting tile 10 comprising a glass or plastic substrate 12 on which metal, for example copper tracks 14 are provided to provide a first electrode connection, in the illustrated example an anode connection. The anode tracks may be provided, for example, by lithographic patterning or by electroless plating onto a printed or lithographically patterned seed layer.

A hole injection layer 16 is deposited over the anode electrode tracking, for example a conductive transparent polymer such as PEDOT:PSS (polystyrene-sulphonate-doped polyethylene-dioxythiophene). This is followed by a light emitting polymer (LEP) stack 18, for example comprising a PPV (poly(p-phenylenevinylene)—based material: The hole injection layer helps to match the hole energy levels of this layer to the anode metal. This is followed by a cathode layer 20, for example comprising a low work function metal such as calcium or barium with an optional electron injection layer (EIL; not shown) such as lithium fluoride or, more preferably, sodium fluoride, or a charge transporting polymer for energy matching, over which is deposited a reflective back (cathode) electrode 22, for example of aluminium or silver. Where an electron injection layer is employed the low work function metal may be omitted. Preferably the light emitting structure is encapsulated to reduce oxygen/moisture ingress and increase device lifetime.

The example of FIG. 1a is a “bottom emitter” device in which light is emitted through the transparent glass or plastic substrate. However a “top emitter” device may also be fabricated in which an upper electrode of the device is substantially transparent, for example fabricated from indium tin oxide (ITO) or a thin layer of cathode metal (say less than 100 nm thickness).

Referring now to FIG. 1b this shows a view of the light emitting tile 10 of FIG. 1a looking towards the LEP stack through the substrate 12, that is looking into the light-emitting face of the device through the “bottom” of the device. This view shows that the anode electrode tracks 14 are, in this example, configured as a hexagonal grid or mesh, in order to avoid obscuring too much light from the LEP stack. The (anode) electrode tracks are connected to a solid copper busbar 30 which runs substantially all the way around the perimeter of the device, optionally with one or more openings, which may be bridged by an electrical conductor) to facilitate that connection to the cathode layer of the device. As described in our earlier patent application, GB2482110A, the grid may be irregular to increase the average in-plane conductivity towards the electrical busbars where greater conductivity is desirable.

Referring again to FIG. 1a, various configurations of the LEP stack 18 are possible. For example this may comprise red green and blue emitting layers to make a white emitter, or alternatively a white emitter may have a single layer incorporating red, green and blue emitting materials/moieties. The LEP stack may incorporate fluorescent and/or phosphorescent layers, optionally with a triplet diffusion protection layer between. Optionally an interlayer (not shown) may be included between the hole injection layer (HIL) and the light emitting layer(s). The interlayer may have a higher hole mobility than electron mobility (by contrast, electron transport is favoured in the light emitting layer(s)), so that electron and hole charges accumulate at the LEP/IL interface, reducing exciton quenching by the cathode and anode. Optionally the interlayer (IL) may incorporate a light-emitting material/moiety, for example a red-emitting material/moiety and optionally a further layer may then incorporate green and blue emitting materials/moieties. For different, coloured lighting stacks with only one or two different colours of emission may be used.

The anode may comprise any material with a work function suitable for injection of holes into the light emitting layer/stack. The hole injection layer preferably comprises a conducting material; it assists hole injection from the anode into the light emitting layer. Representative examples of materials that may be used to form the hole injection layer include PEDOT:PSS, PANI (polyaniline), polypyrole, optionally substituted, doped poly(ethylene dioxythiophene) (PEDT), in particular PEDT doped with a charge-balancing polyacid such as polystyrene sulfonate (PSS) as disclosed in EP0901176 and EP0947123, polyacrylic acid or a fluorinated sulfonic acid, for example Nafion®; polyaniline as disclosed in U.S. Pat. No. 5,723,873 and U.S. Pat. No. 5,798,170; and optionally substituted polythiophene or poly(thienothiophene). Other suitable materials are summarized in the book by Zigang Li and Hong Meng, Chapter 3.3 page 303-12. Examples of conductive inorganic materials include transition metal oxides such as VOₓ, MOₓ and RuOₓ as disclosed in Journal of Physics D: Applied Physics (1996), 29(11), 2750-2753. Suitable materials for use as the hole injection layer are commercially available, e.g. from Plextronics Inc. Where a hole injection layer is employed an auxiliary layer of organic conductive material may optionally be included between the anode electrode tracks and the hole injection layer.

Preferably the hole injection layer is deposited by a solution-based processing method over the anode tracks. Any conventional solution-based processing method may be used. Representative examples of solution-based processing methods include spin coating, gravure printing, flexographic printing, dip coating, slot die coating, doctor blade coating and ink-jet printing. In preferred methods, however, depositing is by spin coating. The parameters used for spin coating the hole injection layer such as spin coating speed, acceleration and time are selected on the basis of the target thickness for the layer. After deposition, the hole injection layer is preferably annealed by heating, e.g. at 150 to 200° C. for 2 to 30 minutes in air. The thickness of the hole injection layer may be in the range 15 to 200 nm, for example around 130 nm. The rest of the LEP stack (including the interlayer where present) may similarly have a thickness of order 100-200 nm.

### Electrodes Containing NiP Alloys

The electrode metal may comprise aluminium, titanium, tantalum, molybdenum or steel but copper is preferred as it is highly conductive and is cheap. Where the structure is such that light shines through an electrode the electrode may be in the form of a regular or irregular grid and/or thin enough to allow light through. Use of a NiP alloy as part of an electrode, in particular the anode, can help to increase device lifetime, it is speculated by mitigating electromigration as well as in other ways.

The NiP may be present as a layer of an electrode; in embodiments the layer comprising NiP alloy has a thickness of 1 nm to 1000 nm, more preferably 1 nm to 200 nm and still more preferably 5 nm to 100 nm. Preferably the layer comprising NiP alloy has a substantially uniform thickness. In embodiments at least one polymeric layer is deposited onto the electrode, for example a hole injection layer. Preferably the polymeric layer comprises acidic groups. Representative examples of hole injection layers include poly(3,4-ethylenedioxythiophene) (PEDOT), PEDOT:PSS, polythiophene conductive polymer, polyaniline (PANI), polypyrole, polyacrylic acid or a fluorinated sulfonic acid, for example Nafion. Preferably the polymeric layer is solution processed. Advantageously the NiP alloy constitutes a hydrophilic layer on the metal and facilitates deposition of polymeric layers by solution processing from water.

In embodiments an electrode comprising an NiP alloy, for example an NiP alloy layer, comprises 1 to 15% wt phosphorus, more preferably 5 to 12% wt and still more preferably 8 to 12% wt phosphorus. The phosphorus content of the NiP alloy is preferably determined by the test set out in ISO4527 Annex D. The amount of phosphorus present in the NiP alloy is important as it can affect the microstructure and performance characteristics of the alloy. Usually NiP alloys comprising greater than about 10% wt phosphorus are amorphous and those comprising less than about 8% wt phosphorus are microcrystalline. Alloys containing an intermediate amount of phosphorus, e.g. 8 to 10% wt are generally semi-crystalline. An NiP alloy may be present in one or both the electrodes of the present invention and may be semi-crystalline or amorphous, more preferably amorphous. Semi-crystalline and particularly amorphous NiP alloys comprise fewer grain boundaries that may act as sites for intergranular corrosion and therefore tend to provide improved corrosion resistance compared to crystalline NiP alloys.

Some preferred NiP alloys present in an electrode comprise 85-99% wt nickel, 1 to 15% wt of phosphorus and 0-2% wt of impurities, e.g. other metal such as Pd. Still further preferred NiP alloys comprise 90-92% wt nickel, 8-10% wt phosphorus, and 0-2% wt of impurities, e.g. other metal such as Pd. Further preferred NiP alloys present in an electrode may consist essentially of, e.g. consist of, nickel and phosphorus. Low amounts (e.g. 0 to 2% wt) of impurities such as a second metal used as a catalyst may be present. Particularly preferred NiP alloys consist of 85-99% wt nickel and 1 to 15% wt of phosphorus, wherein the total weight of nickel and phosphorus is 100%. Still further preferred NiP alloys consist of 90-92% wt and 8-10% wt of phosphorus, wherein the total weight of nickel and phosphorus is 100%.

### Lifetime Improvement

Copper is a low cost metal with a suitable work function for OLED devices, and is potentially useful for anode metal tracking, but devices fabricated using copper suffer from failure due to shorting. Copper is also highly reactive and oxidises when in contact with aqueous materials. These problems are compounded by the preferred method of deposition, electroplating. The inventors have investigated the problems associated with the use of copper and it appears that the presence of the copper: PEDT interface may lead to electromigration of ionic impurities, which is believed to be responsible for the observed phenomena, in particular the very short device lifetime. The device lifetime can be improved by including a protective barrier layer between the copper and the overlying layers, typically an overlying doped interlayer. In the case of copper, protection may be provided by one or more self-assembled monolayers of aromatic thiols in alkaline solutions (Phys Chem Chem Phys. 2010 Aug. 28; 12(32):9230-8, “Copper protection by self-assembled monolayers of aromatic thiols in alkaline solutions”, Caprioli F et al.). Nonetheless the performance of such structures falls well short what is desirable.

The inventors have established that using a pulsed drive scheme with copper electrodes, with or without an intermediate doped barrier layer, can significantly increase the device lifetime as well as improving the initial luminance decay.

Experiments have further established that a biphasic, rectangular pulse drive is preferred with the pulses having a first, forward drive portion and a second, device protection portion. In the forward drive portion of the waveform the OLED device is preferably driven by a defined or programmed forward current (that is, in embodiments, the forward drive portion of the waveform is a current-programmed rather than voltage-programmed drive portion). In the second, device-protect phase of the rectangular pulse waveform preferably the OLED is driven to a defined voltage, in embodiments zero volts. More particularly the OLED is driven so that there is a defined potential difference across the OLED—that is across the anode and cathode electrodes (rather than simply leaving one or other electrode floating). Although in principal a negative, reverse biased may be employed in this second portion of the pulse waveform in practice, surprisingly, this has been found to be less effective than driving to zero volts, which is equivalent to shorting the OLED and cathode during the off phase.

Investigation into the effect of changing the frequency of the waveform suggests that frequencies of around 1 KHz are less effective than lower frequencies. An effective frequency range appears to be around 300-500 Hz, for example around 400 Hz. It may be preferable to employ a higher than 50% on-time duty cycle (percentage of time during which the device is forward driven) to reduce to the overdrive, where this is employed to offset the time-averaged reduction in overall luminosity.

FIG. 1c, in which like elements to those previously described are indicated by like reference numerals, shows, schematically, an ITO-free organic lighting system 100 according to an embodiment of the invention. The system includes an active current/voltage driver device 110 providing an output rectangular pulse drive waveform with a forward current drive portion and a zero volts clamp portion. An output 112 of this driver is connected to the anode electrode tracks 14, for example via the busbar 30 shown in FIG. 1b.

FIG. 1d illustrates a first example of an OLED drive circuit 110a for implementing a drive scheme as described above. A current source 120 provides the constant current drive during the first, on-phase of the pulse and a voltage source 130 provides the defined potential difference drive during the second, off-phase of the pulse. During the on-phase of the pulse switch S1 is closed and S2 is open; during the off-phase S1 is open and S2 is closed. FIG. 1e illustrates a simplified version of the driver of FIG. 1d in which voltage source 130 is absent and switch S2 shorts out the OLED to apply a potential difference of zero volts.

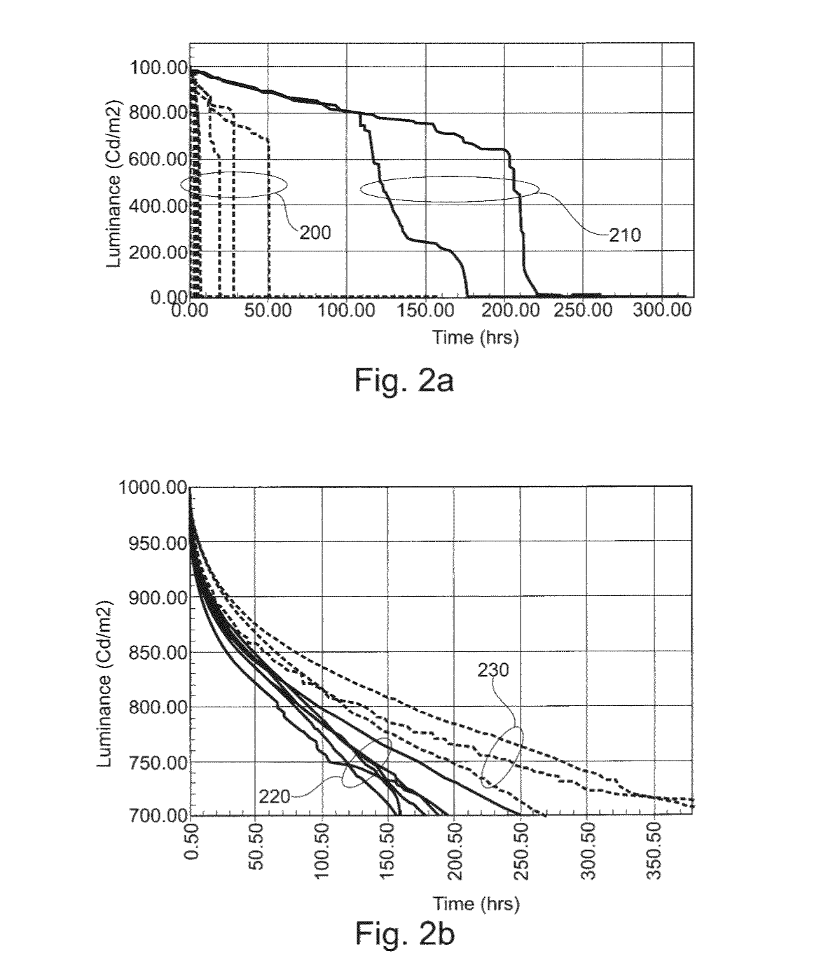

FIG. 2a shows luminance in candelas per square meter against time in hours for a first set 200 of devices driven with direct current, and a second set 210 of devices driven with the arrangement FIG. 1c. As can be seen, the arrangement of FIG. 1c provides a substantially increased device lifetime. A typical OLED lighting element using a copper metal grid of anode tracks without any protective barrier layer generally lasts only a few hours before failure due to shorting (FIG. 2a shows the maximum lifetime obtained as 50 hours). However with a pulse drive at 400 Hz, with zero volts reverse bias, 50% duty cycle, typically lifetimes of 100-200 hours or greater are seen together with a reduced initial decay in luminance.

FIG. 2b shows a second set of results under DC 220 and pulsed 230 drive conditions, with an expanded y-axis. In FIG. 2b the DC structures included various different types of barrier layer between the anode metal and hole injection layer. The same pulsed drive conditions were used as for FIG. 2a and the DC curves are expanded by a factor of 2 in the x-direction to compensate for the pulsed drive being off 50% of the time, thus enabling a fair comparison. (The luminance shown for the pulsed drive scheme is the luminance when the device is on rather than the time-averaged luminance). Again it can be seen that the pulsed drive scheme significantly increases device lifetime and reduces the initial decay in luminance.

Without wishing to be bound by theory we believe that driving the device to zero voltage during a negative cycle is equivalent to reverse biasing the device, since charged impurities will tend to equilibrate due to the built-in field from the differing work functions of the anode and cathode metals. Surprisingly, it is apparently better to actively drive the voltage across the device to zero volts rather than simply disconnecting one or other of the anode and cathode electrodes to leave the device floating, an effect which appears to be related to parasitic capacitance.

Providing an off-portion of the duty cycle may also help to offset any ionic drift induced by the forward bias because, during the off-cycle, more heat can be dissipated than would be the case for a device driven by a DC drive (always on), which may provide a second order benefit to device lifetime from improved heat dissipation during the off-portion. This is counterintuitive since the time-averaged power applied to the device is the same, or for typical OLEDs higher than in the DC case (depending on the drive conditions and the shape of the OLED characteristic curve of lumens per watt efficiency versus luminance).

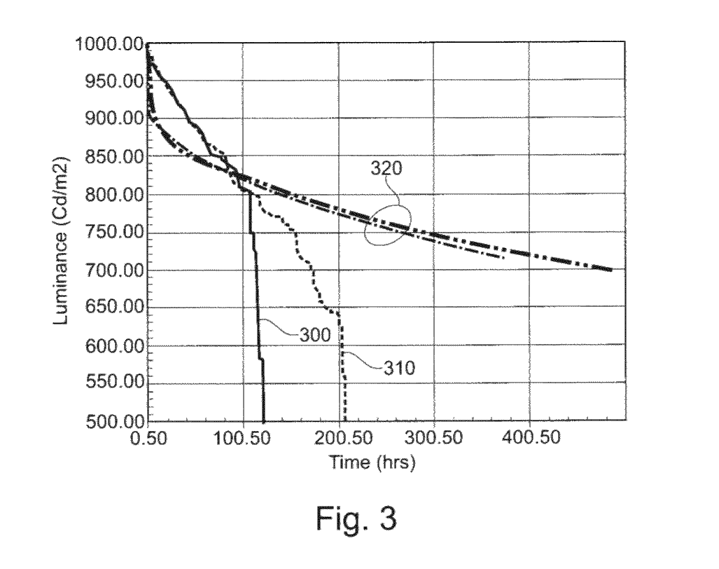

FIG. 3 compares a device with a DC drive and copper anode electrode tracks 300, with a device with a pulsed drive and copper anode electrode tracks 310, and devices with a DC drive and gold anode electrode tracks 320. Although the initial performance of devices with copper tracks is superior (up to around 100 hours) use of gold tracking provides the best overall lifetime. Gold or gold-plated anode electrode tracks may therefore be preferable whether a DC or pulsed drive scheme is employed but gold has the disadvantage of being expensive.

It has been demonstrated that OLED devices with copper metal tracking can have an improved lifetime if a pulsed drive scheme is employed. This facilitates the use of cheaper technology and potentially also removes a requirement for intermediate protection/barrier layers, thus potentially bringing a further cost reduction.

No doubt many other effective alternatives will occur to the skilled person. It will be understood that the invention is not limited to the described embodiments and encompasses modifications apparent to those skilled in the art and lying within the scope of the claims appended hereto.

1. An ITO-free organic lighting system, the system comprising:
a substrate bearing a set of anode electrode metal tracks;
a conductive organic layer over said metal tracks;
an organic light emitting layer over said conductive organic layer; and
a cathode electrode layer over said organic light emitting layer; and
a driver system having an output electronically coupled to said anode electrode metal tracks and to said cathode electrode layer, to drive said organic light emitting layer with a drive current to emit light;
wherein said drive current is pulsed such that an operational lifetime of said lighting system is increased.

2. The ITO-free organic lighting system as claimed in claim 1 wherein said drive current is pulsed such that for a given light output a percentage on-time of said organic light emitting layer is reduced from 100% and a peak value of said driver current is increased to compensate to provide said given light output whilst driving said organic light emitting layer with a reduced on-time.

3. (canceled)

4. The ITO-free organic lighting system as claimed in claim 1 wherein said driver system is configured to drive said organic light emitting layer with a biphasic pulse, said biphasic pulse having a first, on-phase in which said organic light emitting layer is driven with a defined current and a second, off-phase in which said organic light emitting layer is driven with a defined potential difference across the layer.

5. The ITO-free organic lighting system as claimed in claim 4 wherein said anode electrode metal has a higher work function than a cathode metal of said cathode electrode layer; and wherein said defined potential difference is zero volts.

6. The ITO-free organic lighting system as claimed in claim 1 wherein said anode electrode metal comprises copper, in particular wherein said copper has a purity of 98% or greater.

7. The ITO-free organic lighting system as claimed in claim 1 wherein said anode electrode metal comprises a NiP alloy, in particular a copper NiP alloy.

8. The ITO-free organic lighting system as claimed in claim 1 wherein said anode electrode metal tracks are deposited onto said substrate by electroplating or electroless deposition.

9. The ITO-free organic lighting system as claimed in claim 1 wherein said conductive organic layer comprises a hole injection layer.

10. The ITO-free organic lighting system as claimed in claim 9 wherein said hole injection layer comprises a doped conducting polymer, for example, PEDT, optionally substituted.

11. (canceled)

12. The ITO-free organic lighting system as claimed in claim 1 wherein said conductive organic layer is deposited directly over said metal tracks.

13. (canceled)

14. A method of increasing the lifetime of an organic lighting system, the method comprising:
providing an organic lighting element comprising:
a substrate bearing a set of anode electrode metal tracks;
a conductive organic layer over said metal tracks;
an organic light emitting layer over said conductive organic layer; and
a cathode electrode layer over said organic light emitting layer;
wherein said metal comprises copper, and
wherein said conductive organic layer comprises a doped conducting polymer; and
driving said organic lighting element with a pulsed current drive.

15. The method as claimed in claim 14 wherein said doped conductivity polymer comprises PEDT, optionally substituted.

16. The method as claimed in claim 14 wherein said conducting polymer is doped with a charge-balancing polyacid.

17. The method as claimed in claim 14 wherein said conductive organic layer is deposited direct over said anode electrode metal tracks.

18. The method as claimed in claim 14 comprising depositing said copper onto said substrate by electroplating or electroless deposition.

19. The method as claimed in any one of claim 14 wherein said copper is greater than 98% pure.

20. The method as claimed in any one of claim 14 wherein said driving comprises driving said organic lighting element with a biphasic pulse, said biphasic pulse having a first, on-phase in which said organic lighting element is driven with a defined current and a second, off-phase in which said organic lighting element is driven with a defined potential difference across the lighting element.

21. The method as claimed in any one of claim 14 wherein said anode electrode metal has a higher work function than a cathode metal of said cathode electrode layer;
wherein said current drive is a pulsed current drive having a first, forward drive level portion and a second substantially zero level drive portion; and
wherein during said zero level drive portion the different work functions provide a reverse bias electronic field within said lighting element.

22. The method as claimed in any one of claim 14 wherein a duty cycle of said pulsed current drive is in the range 40% to 90%, 95% or 98%, defining a percentage of said forward drive level portion.

23-24. (canceled)

25. The method as claimed in any one of claim 14 wherein said organic lighting element is ITO-free.

26-28. (canceled)
